(19) United States
(12) Patent Application Publication
(10) Pub. No.: US 2025/0183047 A1
(43) Pub. Date: Jun. 5, 2025

(54) SUBSTRATE PROCESSING METHOD AND SUBSTRATE PROCESSING APPARATUS

(71) Applicant: Tokyo Electron Limited, Tokyo (JP)

(72) Inventors: Naoki SHINDO, Nirasaki City (JP); Junichiro MATSUNAGA, Nirasaki City (JP)

(21) Appl. No.: 19/042,043

(22) Filed: Jan. 31, 2025

Related U.S. Application Data
(63) Continuation of application No. PCT/JP2023/033433, filed on Sep. 13, 2023.

(30) Foreign Application Priority Data
Sep. 21, 2022 (JP) 2022-150573

(51) Int. Cl. H01L 21/3065; H01L 21/67

(52) U.S. Cl. CPC H01L 21/3065; H01L 21/67069

(57) ABSTRACT

A substrate processing method includes a first step of supplying processing gases including a halogen-containing gas and a basic gas to a substrate having a recess with side walls formed of a silicon film and an inner wall formed of a germanium-containing film to alter a surface of the silicon film and produce a reaction product, a second step of removing the reaction product to widen a width of the recess, a step of performing a cycle including the first step and the second step multiple times, and a step of performing the first step of a former cycle under a first processing condition and performing the first step of a latter cycle under a second processing condition different from the first processing condition.

### CROSS-REFERENCE TO RELATED APPLICATION

This application is a bypass continuation application of international application No. PCT/JP2023/033433 having an international filing date of Sep. 13, 2023 and designating the United States, the international application being based upon and claiming the benefit of priority from Japanese Patent Application No. 2022-150573, filed on Sep. 21, 2022, the entire contents of which are incorporated herein by reference.

### TECHNICAL FIELD

The present disclosure relates to a substrate processing method and a substrate processing apparatus.

### BACKGROUND

When manufacturing a semiconductor device, there may be a case where the Si film of a Si film and a SiGe film formed on the surface of a semiconductor wafer (hereinafter referred to as a wafer) serving as a substrate is selectively etched. For example, Patent Document 1 describes that the selective etching is performed by using an F₂ gas and an NH₃ gas as etching gases and setting the ratio of the NH₃ gas to the etching gases to a predetermined value.

### PRIOR ART DOCUMENT

### Patent Document

Patent Document 1: Japanese Patent No. 6426489

### SUMMARY

According to one embodiment of the present disclosure, there is provided a substrate processing method including: a first step of supplying processing gases including a halogen-containing gas and a basic gas to a substrate having a recess with side walls formed of a silicon film and an inner wall formed of a germanium-containing film to alter a surface of the silicon film and produce a reaction product; a second step of removing the reaction product to widen a width of the recess; a step of performing a cycle including the first step and the second step multiple times; and a step of performing the first step of a former cycle under a first processing condition and performing the first step of a latter cycle under a second processing condition different from the first processing condition.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a vertical side view of a wafer to be processed according to an embodiment of the present disclosure.

FIG. 2 is an explanatory diagram showing a change in a recess before and after etching.

FIG. 3 is a vertical side view of the wafer after etching.

FIG. 4 is an explanatory diagram showing a change in a Si film that forms the recess.

FIG. 5 is an explanatory diagram showing a change in a Si film that forms the recess.

FIG. 6 is an explanatory diagram showing a change in a Si film that forms the recess.

FIG. 7 is an explanatory diagram showing a change in the recess during etching.

FIG. 8 is an explanatory diagram showing the recess becoming rectangular.

FIG. 9 is an explanatory diagram showing the recess becoming round.

FIG. 10 is a flowchart showing a process according to the present embodiment.

FIG. 11 is a plan view showing an embodiment of a substrate processing apparatus for performing the process.

FIG. 12 is a vertical side view showing an example of a processing module provided in the substrate processing apparatus.

FIG. 13 is a graph showing the results of an evaluation test.

FIG. 14 is a graph showing the results of an evaluation test.

FIG. 15 is a graph showing the results of an evaluation test.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

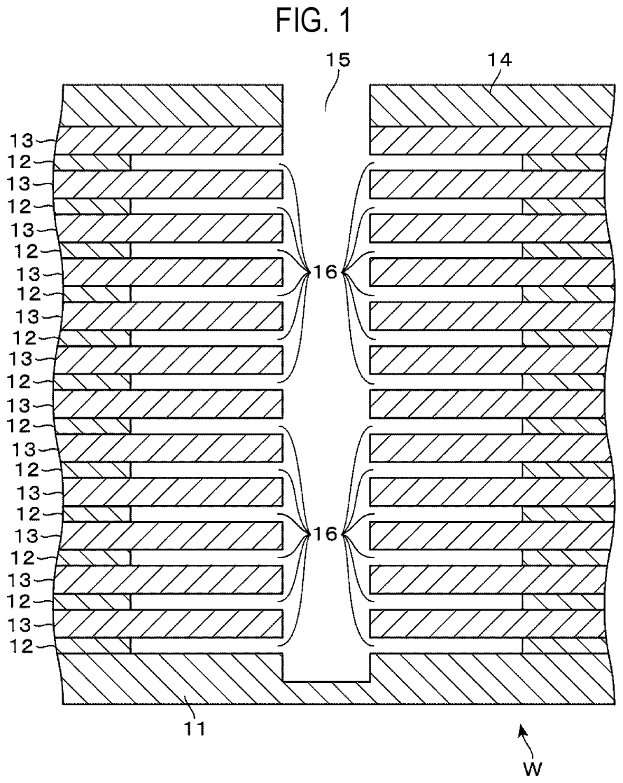

An embodiment of the substrate processing method of the present disclosure will be described. FIG. 1 is a vertical sectional side view of the surface of a wafer W, which is a substrate, showing a state before the etching process according to the present embodiment is performed. An underlayer film 11 is formed on the wafer W. A SiGe (silicon germanium) film 12 and a Si (silicon) film 13 are alternately and repeatedly stacked on the underlayer film 11. With such a repeated structure, each of the SiGe film 12 and the Si film 13 is formed in multiple stages in the thickness direction of the wafer W. The thickness direction of the wafer W will be described as a vertical direction. The Si film 13 is formed, for example, by epitaxial growth.

A mask film 14 is stacked on the uppermost Si film 13 of the above-mentioned repeated structure to prevent the Si film 13 from being etched from above. A recess extending in the vertical direction from the mask film 14 to the upper side of the underlayer film 11 is formed. This recess is a groove 15 extending in the front-to-back direction of the paper surface in FIG. 1. The groove 15 is opened on the upper surface of the mask film 14. The side walls of the groove 15 are formed by the respective surface layer portions of the mask film 14, the Si film 13 and the underlayer film 11, and each SiGe film 12 is located away from the side walls of the groove 15. As a result, in a vertical sectional view, multiple recesses facing the left side are formed at intervals on the left wall of the groove 15, and multiple recesses facing the right side are formed at intervals on the right wall of the groove 15. These recesses facing the left and right sides, respectively, are recesses 16. Therefore, the recesses 16 are formed in multiple stages in the thickness direction of the wafer W, and are formed so as to be opened in a direction intersecting the thickness direction thereof.

The groove 15 and the recesses 16 are formed to form a symmetrical structure, and the vertical widths of the recesses 16 are the same or approximately the same. Hereinafter, the recesses 16 on the upper side of the Si film 13, the recesses 16 on the lower side of the Si film 13, and the recesses 16 between the upper and lower sides of the Si film 13 may be referred to as a top recess 16, a bottom recess 16, and a middle recess 16, respectively. The height of the stacked body formed by the SiGe film 12 and the Si film 13 (=the height from the upper surface of the underlayer film 11 to the lower end of the mask film 14) is, for example, 4 μm.

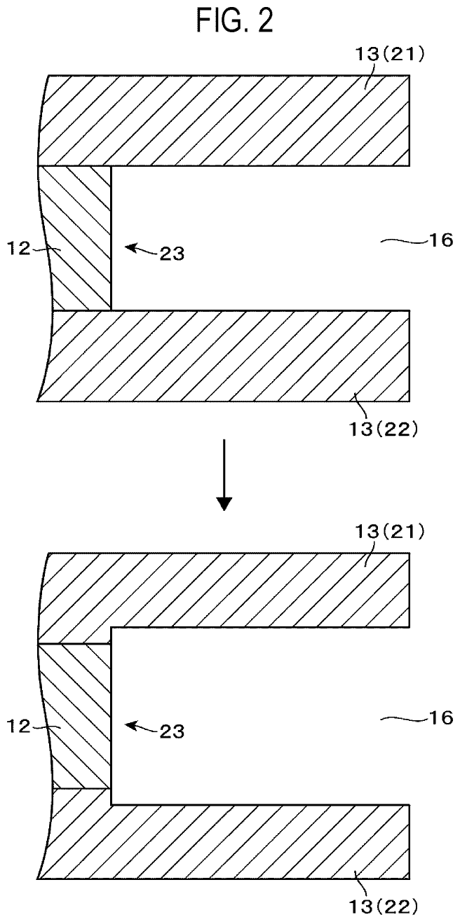

FIG. 2 is an enlarged view of one of the recesses 16. The upper side shows a state before etching, which corresponds to FIG. 1, and the lower side shows a state after etching to be described later. Because of the film structure described above, the side wall of the recess 16 is formed of the Si film 13, and the back wall (bottom wall) is formed of the SiGe film 12. Hereinafter, for the sake of convenience of description, the walls forming each recess 16 may be referred to as an upper wall 21, a lower wall 22, and a side wall 23. The upper wall 21 and the lower wall 22 are composed of the Si film 13, and the upper wall 21 of any one recess 16 is the lower wall 22 of the recess 16 above the one recess 16. The side wall 23 is formed of the SiGe film 12 before etching. In the recess 16 before etching, the upper wall 21 and the lower wall 22 are perpendicular or approximately perpendicular to the side wall 23. In a vertical sectional view, each of the upper wall 21 and the lower wall 22 forms a corner with the side wall 23, and the angle of the corner is 90° or approximately 90°.

When a gas is supplied to the wafer W, the gas is introduced into the groove 15 and further into the recesses 16 of respective stages. In the present embodiment, as described above, the processing gas is introduced into each recess 16 from the surface of the wafer W to thereby etch the lower surface side of the upper wall 21 and the upper surface side of the lower wall 22. That is, the thickness of the Si film 13 forming the side wall of the recess 16 is reduced, and the recess 16 is widened in the vertical direction. Due to this widening, the side wall 23 of the recess 16 after etching is formed of the SiGe film 12 and the Si film 13. FIG. 2 is a schematic diagram showing a desirable state in which the shape of the recess 16 after etching is a rectangular shape, which will be described later, and the roughness of the lower surface of the upper wall 21 and the upper surface of the lower wall 22 is reduced.

Specifically, the etching process is as follows. An F₂ (fluorine) gas, which is a halogen-containing gas, and an NH₃ gas, which is a basic gas, are supplied to the wafer W as processing gases, and the surface of the Si film 13 constituting the upper wall 21 and the lower wall 22 is altered to generate a reaction product. The process of altering the Si film 13 by the processing gases is called a processing gas supply process. Then, a heating process is performed in which the wafer W is heated to sublimate the reaction product and widen the recess 16. The reaction product to be sublimated includes various products such as AFS, which will be described later. The vertical width of the recess 16 is made to a desired size by repeating a cycle consisting of the processing gas supply process, which is a first process, and the heating process, which is a second process. Each of the processing gas supply process and the heating process is performed in a state in which the wafer W is accommodated in a processing container in which a vacuum atmosphere is formed under a predetermined pressure.

The above-mentioned processing gases act mainly on the Si film 13 out of the Si film 13 and the SiGe film 12. Therefore, the Si film 13 is etched selectively with respect to the SiGe film 12. The above-mentioned reaction product is ammonia fluorosilicate [AFS:(NH₄)SiF₆]. In the following description, unless otherwise specified, the processing gas supply time refers to the processing gas supply time in one cycle, and refers to the time during which both the F₂ gas as a halogen-containing gas and the NH₃ gas as a basic gas are supplied to the wafer W.

It is desired that the recess 16 after etching meets the first to third requirements described below. The first requirement is that the roughness (surface roughness) of the lower surface of the upper wall 21 and the upper surface of the lower wall 22, which are the Si film 13, be relatively small. The second requirement is described below. Even after etching, as before etching, the upper wall 21 and the lower wall 22 and the side wall 23 form an angle of 90° or approximately 90° on the inner side of the recess 16. The formation of such an angle results in high uniformity of the vertical width between the opening side and the inner side of the recess 16. For the sake of convenience of description, the shape of the recess 16 in which such an angle is formed and the uniformity of the vertical width is high will be described as a rectangular shape. On the other hand, the shape of the recess 16 in which such an angle is not formed, the recess 16 is a horizontally inclined U-shape in a vertical cross section, and the vertical width on the inner side is smaller than that on the opening side will be described as a round shape. The second requirement is that the shape of the recess 16 be closer to a rectangular shape (the rectangularity be high).

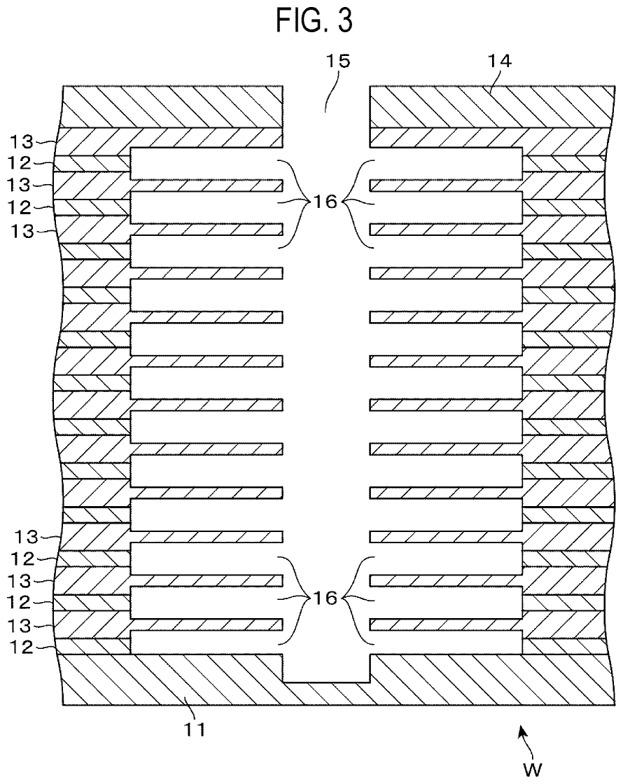

The third requirement is that the variation in the vertical widths of the recesses 16 at respective heights be suppressed. In other words, the third requirement is that the variation in the amount of etching be suppressed among the top, middle, and bottom recesses 16. FIG. 3 is a schematic diagram showing a state in which the wafer W in FIG. 1 has been etched to meet the above-mentioned first to third requirements. The recess 16 after etching shown in FIG. 2 described above is one of the recesses 16 of the wafer W shown in FIG. 3.

The roughness of the Si film 13 regarding the first requirement will be described in detail. The Si film 13 reacts with the F₂ gas and the NH₃ gas, which are the processing gases, as shown in the following formula 1 to produce a product (SiF₄). This SiF₄ reacts as shown in formula 2 to produce AFS. The roughness of the Si film 13 after etching varies depending on the processing conditions, but it is thought that the amount of AFS produced during the processing gas supply process involves the roughness of the Si film 13 after etching.

Si+F₂+NH₃→SiF₄+NH₃ formula 1

SiF₄+H₂+F₂+2NH₃→(NH₄)SiF₆ formula 2

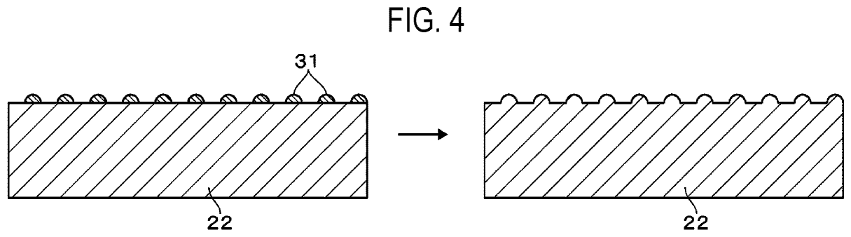

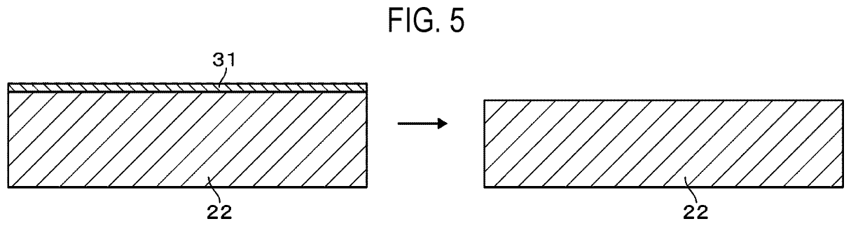

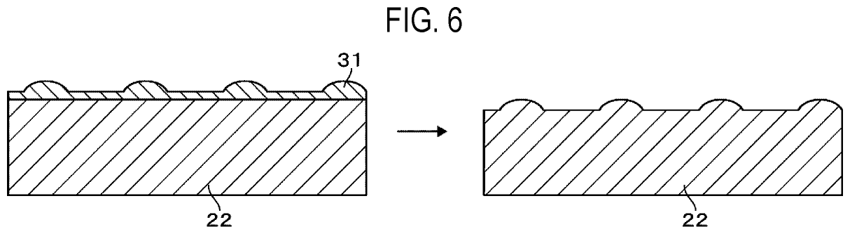

Hereinafter, differences in roughness that are believed to be caused by differences in the amount of AFS produced will be described with reference to FIGS. 4 to 6. FIGS. 4 to 6 schematically show a change in the upper surface of the lower wall 22 of the recess between when the processing gases are supplied and after the etching is completed. The lower surface of the upper wall 21 is also changed in the same manner as the upper surface of the lower wall 22. The amount of AFS produced during the processing gas supply process increases in the order of FIG. 4, FIG. 5, and FIG. 6.

FIG. 4 shows a state in which the AFS layer 31 is formed in a dotted manner on the upper surface of the lower wall 22 during the processing gas supply process due to a relatively small amount of AFS produced. The portion of the upper surface covered with the AFS layer 31 is prevented from contacting the processing gases, and is less likely to be altered by the reaction with the processing gas. That is, the reactivity to the processing gases differs between the portion of the upper surface of the lower wall 22 where the AFS layer 31 is formed and the portion of the upper surface of the lower wall 22 where the AFS layer 31 is not formed. Due to the difference in reactivity, depressions and protrusions are formed on the surface of the lower wall 22 after etching. Since the AFS layer 31 is formed in a dotted manner as described above, the surface roughness of the upper surface of the lower wall 22 is small. That is, the width of the depressions and the width of the protrusions in the above-mentioned depressions and protrusions are relatively small.

Referring to FIG. 5, the AFS layer 31 is formed as a thin layer covering the entire upper surface of the lower wall 22 during the processing gas supply process, thereby suppressing the reaction with the processing gases to the same extent in the respective portions of the upper surface. As a result, the entire upper surface of the lower wall 22 is etched with high uniformity, and the surface after etching becomes flat or approximately flat.

FIG. 6 shows a state in which a relatively large amount of AFS is produced during the processing gas supply process so that the AFS layer 31 covers the entire upper surface of the lower wall 22 and the thickness of the AFS layer 31 varies at various portions of the upper surface. That is, the surface roughness of the AFS layer 31 is large. The thicker the AFS layer 31 is, the more difficult it becomes for the processing gases to come into contact with the lower wall 22. Therefore, the surface roughness of the lower wall 22 after etching also becomes large. That is, the width of the depressions and the width of the protrusions in depressions and protrusions are relatively large.

The state in which the surface roughness is relatively small as shown in FIG. 4 is called micro-roughness, and the state in which the surface roughness is relatively large as shown in FIG. 6 is called large roughness. As described above, when the amount of AFS produced shifts from an appropriate range to the smaller side, the surface roughness of the Si film 13 due to micro-roughness increases, and when the amount of AFS produced shifts to the larger side, the surface roughness of the Si film 13 due to large roughness increases. According to the above formulas 1 and 2, the amount of AFS produced is influenced by the flow rate ratio of the F₂ gas and the NH₃ gas, which are processing gases supplied to the wafer W. When the flow rate of the NH₃ gas to the flow rate of the F₂ gas is relatively large, the amount of AFS produced increases. In addition, the amount of AFS produced increases as the processing gas supply time increases. Incidentally, the flow rate of the NH₃ gas to the flow rate of the F₂ gas in the processing gases (the flow rate of the NH₃ gas/the flow rate of the F₂ gas) may be herein after referred to as a NH₃ gas flow rate ratio. Therefore, a high NH₃ gas flow rate ratio means that the flow rate of the NH₃ gas is high relative to the flow rate of the F₂ gas (=the ratio of the NH₃ gas to the ratio of the F₂ gas in the processing gases is high).

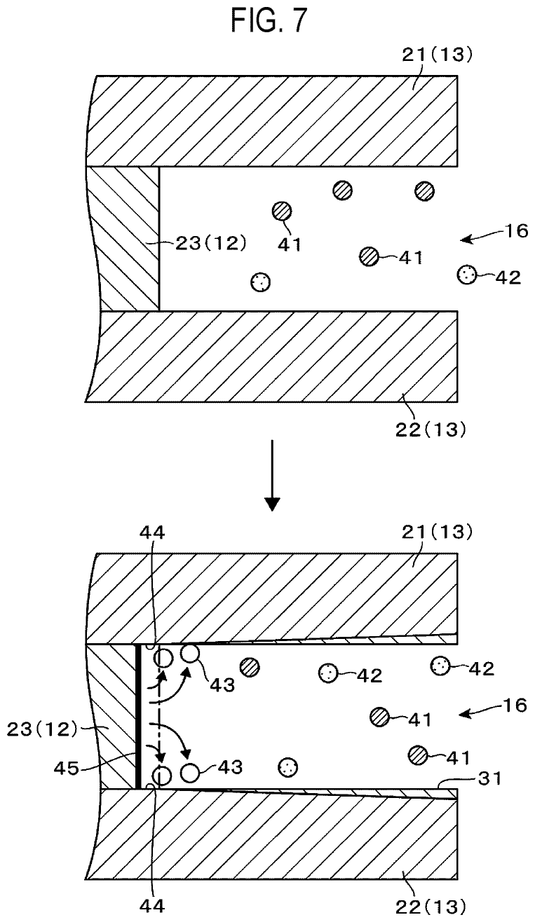

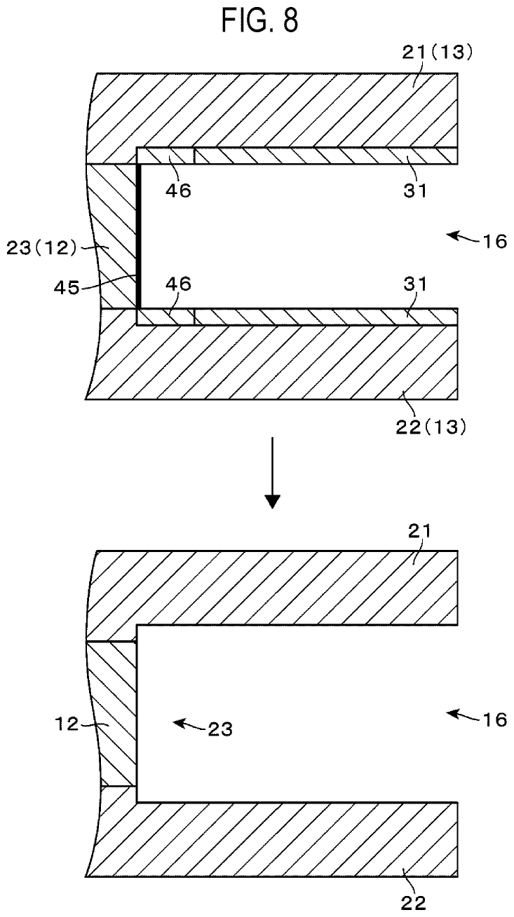

Next, the shape of the recess 16 after etching regarding the second requirement will be described. Depending on the processing conditions, the shape of the recess 16 after etching is changed between a rectangular shape and a round shape. The process presumed to occur until the rectangular shape and the round shape are formed will be described below. Referring first to FIGS. 7 and 8, the presumed process of forming the rectangular shape will be described. The F₂ gas 41 and the NH₃ gas 42, which are processing gases, enter the recess 16 (upper part in FIG. 7) and react with the lower surface of the upper wall 21 and the upper surface of the lower wall 22, which are the Si film 13, as indicated in the above-mentioned formula 1, to generate SiF₄. A portion of this SiF₄ is released into the recess 16 as a gas, while another portion thereof reacts as indicated in the above-mentioned formula 2 to form the AFS layer 31.

The F₂ gas 41 and the NH₃ gas 42 act on the side wall 23 in addition to the upper wall 21 and the lower wall 22. The surface layer of the SiGe film 12 constituting the side wall 23 is altered and slightly etched, releasing a GeF₄ (germanium tetrafluoride) gas 43. By etching the side wall 23 in this way, a portion of the Si film 13 is newly exposed in the recess 16 on the inner of the recess 16, thereby forming the upper wall 21 and the lower wall 22 of the recess 16 (lower part in FIG. 7). This portion is called a newly exposed portion 44.

The newly exposed portion 44 is exposed to the recess 16 during the supply of the processing gases and, therefore, is exposed to the F₂ gas 41 and the NH₃ gas 42 for a shorter period of time than the portions of the Si film 13 that form the upper wall 21 and the lower wall 22 before etching. Therefore, the amount of reaction with the F₂ gas 41 and the NH₃ gas 42 is relatively small. In addition, the F₂ gas 41 and the NH₃ gas 42 are less likely to enter the recess 16 toward the inner side. From the above, the amount of reaction with the F₂ gas 41 and the NH₃ gas 42 is smaller in the inner side of the recess 16 for the upper wall 21 and the lower wall 22 including the newly exposed portion 44. However, the GeF₄ gas 43 is reactive with the Si film 13, and is generated from the SiGe film 12. The GeF₄ gas 43 reacts relatively strongly with the Si film 13 on the inner side of the recess 16. Therefore, the Si film 13 reacts with high uniformity from the opening of the recess 16 to the inner side (upper part in FIG. 8). Accordingly, after the reaction products generated in the processing gas supply process are removed by the heating process, the recess 16 becomes rectangular (lower part in FIG. 8). The AFG layer, which is a reaction product produced in the SiGe film 12, is designated by 45, and the reaction product between the GeF₄ gas 43 and the Si film 13 is designated by 46. The AFG layer 45 and the reaction product 46 are also removed together with the AFG layer 45. The AFG layer 45 will be described later.

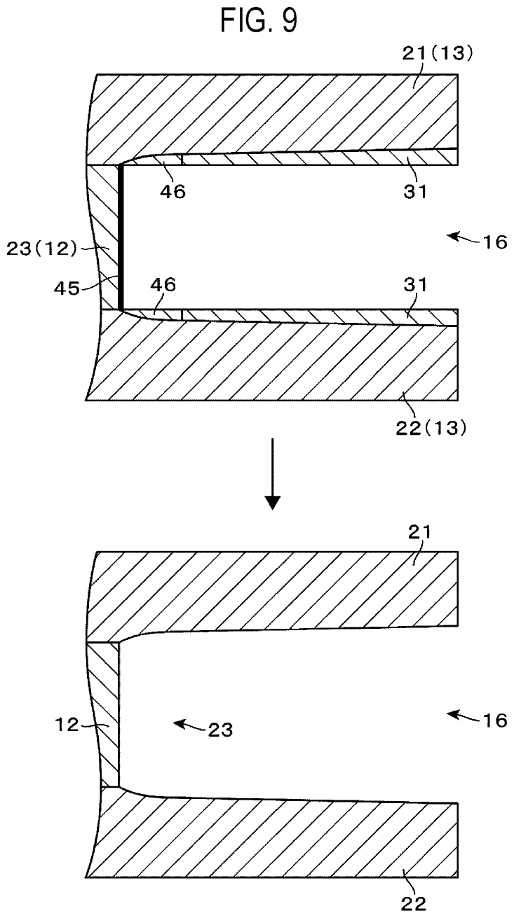

Next, the presumed process of forming the round shape will be described. When the reaction between the surface layer of the SiGe film 12 and the processing gases proceeds from the state shown in the lower part in FIG. 7, the surface layer is gradually changed to the AFG [(NH₄)GeF₆] layer 45. As the change to the AFG layer 45 proceeds, the amount of GeF₄ gas 44 released decreases. Accordingly, the reaction amount of the upper wall 21 and the lower wall 22 with the GeF₄ gas 44 and/or the F₂ gas 41 and the NH₃ gas 42 decreases toward the inner side of the recess 16 (upper part in FIG. 9). Therefore, after the reaction products are removed by the heating process, the recess 16 becomes round (lower part in FIG. 9). From the above, the longer the processing gas supply time or the larger the NH₃ gas flow rate ratio, the easier it is to form the AFG layer 45 (=the easier it is to reduce the release of the GeF₄ gas 44), and the easier it is to form the round shape.

Next, the variation in the amount of etching among the top, middle, and bottom regarding the third requirement will be described. Since the processing gases are less likely to enter toward the inner side of the groove 15, when the processing gas is supplied for a relatively short time, the upper wall 21 and the lower wall 22 of the recess 16 are more likely to come into contact with the processing gases and react with the processing gases in the order of top>middle>bottom. Accordingly, the amount of etching increases in this order.

However, as shown in the evaluation tests described later, it has been confirmed that the longer the processing gas supply time, the greater the amount of etching becomes in the bottom side (i.e., the order of the amount of etching becomes top<middle<bottom). This is considered to be due in part to the fact that the longer the processing gas supply time, the thicker the AFS layer 31 formed becomes in the top side (the opening side of the groove 15), thereby preventing the upper wall 21 and the lower wall 22 from reacting with the processing gases. Furthermore, the greater the flow rate of the NH₃ gas, the easier it is for the thickness of the AFS layer 31 on the top side to increase, and the greater the amount of etching tends to be in the bottom side.

As described above, by setting the processing conditions in which the NH₃ gas flow rate ratio is relatively small and/or the processing gas supply time is relatively short, the recess 16 after etching tends to have micro-roughness, a rectangular shape, and a large amount of etching on the top side. Conversely, by setting the processing conditions in which the NH₃ gas flow rate ratio is relatively large and/or the processing gas supply time is relatively long, the recess 16 after etching tends to have large roughness, a round shape, and a large amount of etching on the bottom side. Regarding the NH₃ gas flow rate ratio and the processing gas supply time, the appropriate range for keeping the roughness within an allowable range, the appropriate range for forming the rectangular shape, and the appropriate range allowing for the uniform amount of etching between the top and bottom do not necessarily coincide. Therefore, when the cycle consisting of the processing gas supply process and the heating process is repeatedly performed, if the processing gas supply process of each cycle is set to the same processing conditions, it is difficult to fully meet all of the above-mentioned first to third requirements.

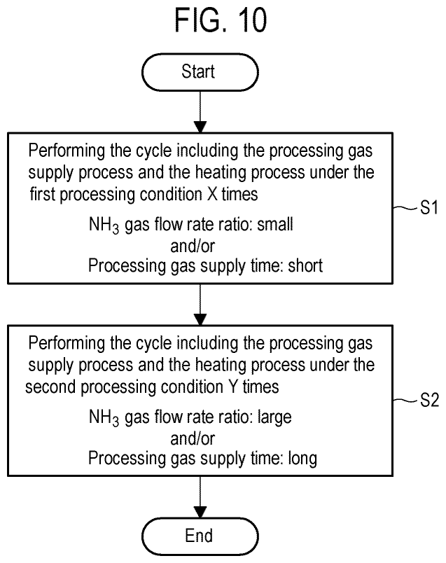

Therefore, in the present embodiment, the processing conditions are set to be different between the processing gas supply process performed in the former stage cycle and the processing gas supply process performed in the latter stage cycle. FIG. 10 shows a process flow in the present embodiment. Assuming that the cycle is set to be performed Z times in total, the processing gas supply process is performed under a first processing condition, and then the heating process is performed. This is repeated X times in the former stage cycle (step S1). Then, the processing gas supply process is performed under a second processing condition, and then the heating process is performed. This is repeated Y times (Z times-X times) in the latter stage cycle (step S2).

By changing the processing conditions as described above, it is possible to prevent a particular tendency from appearing strongly in the roughness, the shape of the recess, and the etching amount between the top, middle, and bottom, as compared with a case where processing is performed under a single processing condition, and to meet the first to third requirements. However, as will be shown later as an evaluation test, it has been confirmed that the shape and roughness of the recess 16 after etching are relatively more affected by the processing conditions performed in the former stage cycle than in the latter stage cycle. In other words, when the processing gas supply process in the former stage cycle is performed under conditions in which the rectangular shape and the micro-roughness are obtained, the recess 16 after etching tends to have the rectangular shape and the micro-roughness. Conversely, when the processing gas supply process in the former stage cycle is performed under conditions that the round shape and the large roughness are obtained, the recess 16 after etching tends to have the round shape and the large roughness.

It is sufficient that the roughness falls within a tolerance even if it is formed slightly. Therefore, for the purpose of forming the rectangular shape, the first processing condition in the former stage cycle may be a processing condition that tends to obtain the rectangular shape and the micro-roughness, and the second processing condition in the latter stage cycle may be a processing condition that tends to obtain the round shape and the large roughness compared to the first processing condition. Therefore, specifically, the NH₃ gas flow rate ratio is made smaller in the first processing condition than in the second processing condition, or the processing gas supply time is made shorter in the first processing condition than in the second processing condition. Furthermore, in order to increase the tendency to form the rectangular shape, it is preferable that after setting the first processing condition in the former stage cycle and the second processing condition in the latter stage cycle, for example, the number of times the former stage cycle is performed (X times) are set to be greater than or equal to the number of times the latter cycle is performed (Y times).

In addition, there may be a case where the first requirement (requirement to reduce roughness) is more important than the second requirement (requirement to increase rectangularity). In that case, as described above, the influence of the first processing condition in the former stage cycle remains relatively large on the recess 16 after etching. Therefore, a condition that relatively reduces roughness is selected as the first processing condition. Then, a condition that corrects the etching amount between the top, middle, and bottom and changes the shape of the recess 16 so as to increase the rectangularity may be selected as the second processing condition in the latter stage cycle. Specifically, the NH₃ gas flow rate ratio is made smaller in the first processing condition than in the second processing condition, or the processing gas supply time is made shorter in the first processing condition than in the second processing condition. In this way, even when a high roughness reduction effect is intended to obtain, for the purpose of increasing the effect, it is preferable that, for example, the number of times the former stage cycle is performed (X times) is set to be greater than or equal to the number of times the latter stage cycle is performed (Y times).

In the present embodiment, in order to increase the rectangularity, the NH₃ gas flow rate ratio is set to be smaller in the first processing condition than in the second processing condition, the processing gas supply time is set to be shorter in the first processing condition than in the second processing condition, and the number of times the first cycle is performed (X times) is set to be greater than the number of times the second cycle is performed.

As a more specific example of the processing conditions, the NH₃ gas flow rate ratio (the flow rate of the NH₃ gas/the flow rate of the F₂ gas) is set to fall, for example, within a range of 0.01 to 0.014 in each of the first processing condition and the second processing condition, based on the results of the evaluation tests described later. Therefore, the NH₃ gas flow rate ratio in at least one of the first processing condition and the second processing condition is smaller than 0.014. In addition, the processing gas supply time is set to fall, for example, within a range of 10 seconds to 15 seconds in each of the first processing condition and the second processing condition. In this specification, the processing gas supply time is the time during which the halogen-containing gas (F₂ gas in the present embodiment) and the basic gas (NH₃ gas in the present embodiment) constituting the processing gases are simultaneously supplied to the wafer W (i.e., the time during which they are supplied into the processing container that accommodates the wafer W).

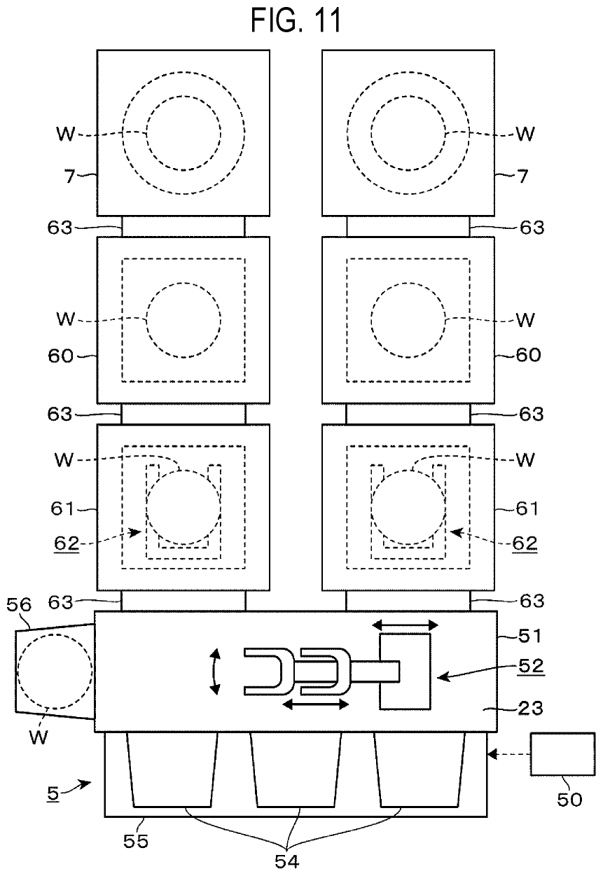

A substrate processing apparatus 5, which is one embodiment of the apparatus for performing the processing described in the flowchart of FIG. 10, will be described with reference to a plan view of FIG. 11. The substrate processing apparatus 5 includes a loading/unloading part 51 for loading and unloading a wafer W, two load lock chambers 61 provided adjacent to the loading/unloading part 51, two thermal processing modules 60 provided adjacent to the two load lock chambers 61, respectively, and two processing modules 7 provided adjacent to the two thermal processing modules 60, respectively. The processing module 7 corresponds to a first processing part, and the thermal processing module 60 corresponds to a second processing part.

The loading/unloading part 51 includes an atmospheric pressure transfer chamber 53 provided with a first substrate transfer mechanism 52 and kept under an atmospheric pressure, and a carrier placement table 55 on the side of the atmospheric pressure transfer chamber 53 on which a carrier 54 storing wafers W is placed. In the drawing, reference numeral 56 denotes an aligner arranged adjacent to the atmospheric pressure transfer chamber 53. The aligner 56 is provided to rotate the wafer W to optically obtain an amount of eccentricity and to align the wafer W with respect to the first substrate transfer mechanism 52. The first substrate transfer mechanism 52 transfers the wafer W between the carrier 54 on the carrier placement table 55, the aligner 56, and the load lock chamber 61.

A second substrate transfer mechanism 62 having, for example, a multi-joint arm structure is provided in each load lock chamber 61. The second substrate transfer mechanism 62 transfers the wafer W between the load lock chamber 61, the thermal processing module 60, and the processing module 7. The inside of the processing container constituting the thermal processing module 60 and the inside of the processing container constituting the processing module 7 are kept in a vacuum atmosphere, and the inside of the load lock chamber 61 can be switched between an atmospheric pressure atmosphere and a vacuum atmosphere so that the wafer W can be transferred between the inside of the processing container kept in the vacuum atmosphere and the atmospheric pressure transfer chamber 53.

In the drawing, reference numeral 63 denotes openable/closable gate valves that are provided between the atmospheric pressure transfer chamber 53 and the load lock chamber 61, between the load lock chamber 61 and the thermal processing module 60, and between the thermal processing module 60 and the processing module 7, respectively. The thermal processing module 60 includes the above-mentioned processing container, an evacuation mechanism for evacuating the inside of the processing container to form a vacuum atmosphere, and a stage provided in the processing container and capable of heating the wafer W placed thereon, and the like. The thermal processing module 60 is configured to be able to execute the heating process described above.

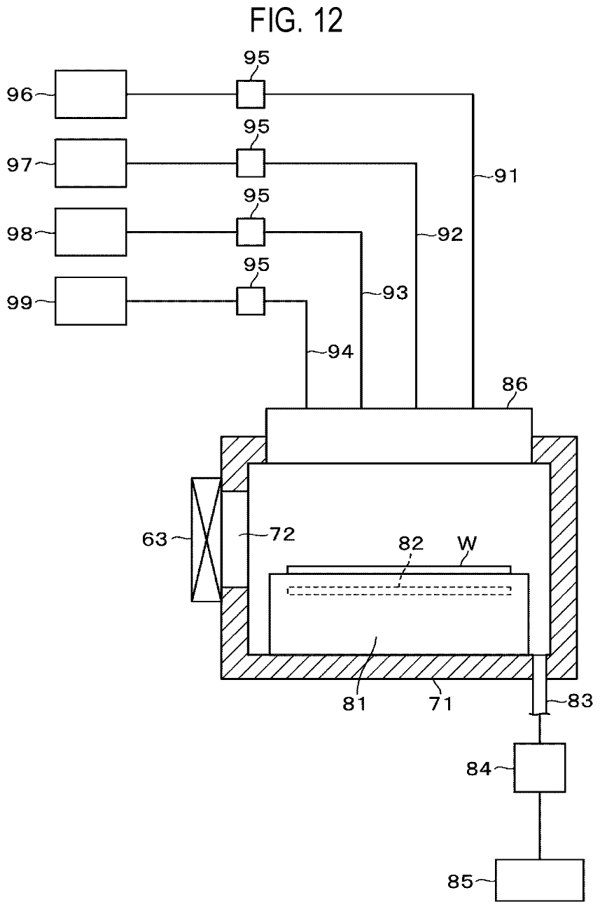

The processing module 7 will be described with reference to the vertical side view of FIG. 12. The processing module 7 executes the processing gas supply process described above. In the drawing, reference numeral 71 denotes a processing container constituting the processing module 7. In the drawing, reference numeral 72 denotes a transfer port for the wafer W formed in the side wall of the processing container 71. The transfer port 72 is opened and closed by the gate valve 63 described above. A stage 81 for placing the wafer W thereon is provided in the processing container 71. The stage 81 is provided with lift pins (not shown). The wafer W is delivered between the second substrate transfer mechanism 62 and the stage 81 via the lift pins.

A temperature regulator 82 is embedded in the stage 81, and the wafer W placed on the stage 81 is adjusted to the temperature described below. The temperature regulator 82 is configured as a flow path that is a part of a circulation path through which a temperature adjustment fluid such as water or the like flows. The temperature of the wafer W is adjusted by heat exchange with the fluid. However, the temperature regulator 82 is not limited to being a flow path for such a fluid, and may be configured, for example, by a heater for performing resistance heating.

One end of an exhaust pipe 83 is opened into the processing container 71, and the other end of the exhaust pipe 83 is connected to an evacuation mechanism 85 constituted by, for example, a vacuum pump via a valve 84, which is a pressure changing mechanism. By adjusting the opening degree of the valve 84, the pressure inside the processing container 71 is set to the pressure range described later, and processing is performed.

A gas shower head 86, which is a processing gas supply mechanism, is provided at the upper side of the processing container 71 so as to face the stage 81. The downstream sides of gas supply paths 91 to 94 are connected to the gas shower head 86, and the upstream sides of the gas supply paths 91 to 94 are connected to gas supply sources 96 to 99 via flow rate regulators 95, respectively. Each flow rate regulator 95 includes a valve and a mass flow controller. The gases supplied from the gas supply sources 96 to 99 are supplied to the downstream side and cut off by opening and closing a valve included in the flow rate regulator 95.

An F₂ gas, an NH₃ gas, an Ar (argon) gas, and an N₂ (nitrogen) gas are supplied to the gas supply sources 96, 97, 98, and 99, respectively. Thus, the HF gas, the NH₃ gas, the Ar gas, and the N₂ gas can be supplied into the processing container 71 from the gas shower head 86. The Ar gas and the N₂ gas are supplied into the processing container 71 as carrier gases together with the F₂ gas and the NH₃ gas.

As shown in FIG. 11, the substrate processing apparatus 5 includes a controller 50, which is a computer. The controller 50 includes a program, a memory, and a CPU. The program includes instructions (respective steps) for processing and transferring the wafer W as described above. The program is stored in a non-transitory computer-readable storage medium, such as a compact disk, a hard disk, a magneto-optical disk, or a DVD, and is installed in the controller 50. The controller 50 outputs control signals to the respective parts of the substrate processing apparatus 5 according to the program, and controls the operations of the respective parts. Specifically, the operation of the processing module 7, the operation of the thermal processing module 60, the operation of the first substrate transfer mechanism 52, the operation of the second substrate transfer mechanism 62, and the operation of the aligner 56 are controlled by the control signals. The operation of the processing module 7 includes, for example, the adjustment of the temperature of the fluid supplied to the stage 81, the supply and cut-off of each gas from the gas shower head 86, and the adjustment of the exhaust flow rate by the valve 84.

The transfer path of the wafer W in the substrate processing apparatus 5 will be described. The carrier 54 storing wafers W on which the respective films are formed as shown in FIG. 1 is placed on the carrier placement table 55. The wafer W is transferred in the order of the atmospheric pressure transfer chamber 53→the aligner 56→the atmospheric pressure transfer chamber 53→the load lock chamber 61, and is transferred to the processing module 7 via the thermal processing module 60. Then, as described above, the processing gas supply process is performed, and the surface layers of the upper wall 21 and the lower wall 22 forming the recess 16 are altered to become AFS layers 31. Next, the wafer W is transferred to the thermal processing module 60, and the AFS layer 31 and other reaction products are sublimated. Thereafter, the wafer W is transferred to reciprocate between the processing module 7 and the thermal processing module 60, and a cycle consisting of the processing gas supply process and the heating process is repeated.

Among the above cycles, in the first to X^{th} cycles, the processing gas supply process is performed under the first processing condition as shown in FIG. 10. Then, in the X+1^{th} and subsequent cycles, the processing gas supply process is performed under the second processing condition in which the NH₃ gas flow rate ratio is increased and the processing gas supply time is lengthened. The cycle performed under the second processing condition is repeated Y times. When Z (X+Y) cycles in total are completed and each recess 16 has a desired vertical width as shown in FIG. 3, the wafer W is transferred from the thermal processing module 60 to the load lock chamber 61 and then to the atmospheric pressure transfer chamber 53, and is returned to the carrier 54.

The processing gas supply process in the above-described cycles will be supplementarily described. In the processing gas supply process, the inside of the processing container 71 of the processing module 7 is evacuated to, for example, 100 mTorr (13.3 Pa) to 10 Torr (1333 Pa), and the temperature of the wafer W is adjusted to, for example, −20 degrees C. to 60 degrees C. In this state, the F₂ gas and the NH₃ gas are supplied into the processing container 71 in parallel (step T1). The time for supplying the F₂ gas and the NH₃ gas and the flow rate ratios of the F₂ gas and the NH₃ gas in step T1 are the processing gas supply time and the NH₃ gas flow rate ratio, which have been described so far. After the supply of the F₂ gas and the NH₃ gas is stopped, an N₂ gas is supplied into the processing container 71 together with the evacuation of the inside of the processing container 71, so that the F₂ gas and the NH₃ gas remaining in the processing container 71 are purged (step T2). After this purging, the wafer W is unloaded from the processing container 71. Supplementarily explaining the heating process in the above-described cycles, in the heating process, the wafer W is heated to a temperature higher than the temperature of the wafer W in steps T1 and T2, for example, to a temperature in a range of 80 degrees C. to 300 degrees C., thereby sublimating the above-mentioned reaction products.

According to the present embodiment described above, the first to third requirements can be met by setting different processing conditions in the processing gas supply processes for the former stage cycle and the latter stage cycle. That is, for the recess 16 after etching, the roughness of the Si film 13 forming the upper wall 21 and the lower wall 22 can be reduced, the recess 16 can be made rectangular, and the variation in the vertical width of the recess 16 between the top, middle, and bottom can be suppressed. Accordingly, it is possible to increase the yield of semiconductor products manufactured from the wafer W after etching.

Although the number of times the former stage cycle is performed, X times, and the number of times the latter stage cycle is performed, Y times, have been described as being multiple times, the X times and/or the Y times may be one time. Therefore, the former stage cycle and the latter stage cycle do not have to be performed repeatedly. Furthermore, in the examples described above, the NH₃ gas flow rate ratio or the processing gas supply time in the processing gas supply process is changed only once, resulting in a two-stage process consisting of the former stage cycle and the subsequent latter stage cycle. The process is not limited to being two-stage, and the processing conditions may be changed two or more times to result in a three or more stage process.

As described above, when performing the two-stage process, in order to form the rectangular shape, it is preferable to set the NH₃ gas flow rate ratio to be smaller in the former stage cycle than in the latter stage cycle, or to set the processing gas supply time to be shorter in the former stage cycle than in the latter stage cycle. Furthermore, as described above, it is preferable to set the number of cycles in the former stage cycle to be equal to or greater than the number of cycles in the latter stage cycle. In the case of performing a three or more stage process, for example, the processing conditions of the first stage and the processing conditions of the second and subsequent stages may have such a relationship, and the number of cycles may be set such that, for example, the number of cycles of the first stage is greater than or equal to the number of cycles of the second and subsequent stages.

In the present embodiment, the atmosphere around the wafer W is kept in a vacuum atmosphere from the start of the first cycle to the end of the last cycle. However, for example, the respective cycles may be performed in different apparatuses, and the wafer W may be moved between the apparatuses through an air atmosphere. From the viewpoint of preventing a decrease in throughput, it is preferable to perform processing in a vacuum atmosphere around the wafer W from the first cycle to the last cycle, as in the case of using the above-described substrate processing apparatus 5.

Incidentally, after the processing gas supply process is performed and before the heating process is performed in any cycle, a second fluorine-containing gas may be supplied to further reduce the roughness after the etching of the Si film 13. The second fluorine-containing gas (i.e., halogen-containing gas) is, for example, a HF (hydrogen fluoride) gas, and is therefore a different type of gas from the first fluorine-containing gas, F₂ gas, constituting the process gases. The HF gas is supplied to the wafer W in the processing module 7.

The processing procedure in the processing module 7 when supplying the HF gas will be described. After the supply of processing gas (step T1) and the purging of the inside of the processing container 71 (step T2) described above are performed in order, the HF gas is supplied into the processing container 71 (step T3). After the supply of the HF gas is stopped, in step T4, the processing container 71 is supplied with an N₂ gas and evacuated as in step T2, and the remaining HF gas is purged. Thereafter, the wafer W is unloaded from the processing module 7. In addition, when supplying the HF gas, which is a roughness reducing gas, in this way, steps T1 to T4 correspond to a first process, step T1 in which both the halogen-containing gas (F₂ gas) and the basic gas (NH₃ gas) are supplied corresponds to a first supply process, and step T3 in which only one of these gases is supplied corresponds to a second supply process.

It is believed that the supply of the HF gas causes the NH₃ contained in the AFS layer 31 formed in step T1 to react with the HF gas to produce a reaction product, and the reaction product slightly etches the surface layer of the Si film 13 coated on the AFS layer 31, thereby reducing roughness.

The processing module 7 performing the above steps T1 to T4 is configured such that, in addition to the gas supply sources 96 to 99 already described, a HF gas supply source is provided and connected to the gas shower head 86 via a flow path. A flow rate regulator 95 is provided in the HF gas flow path, as in the flow paths of other gases, and the HF gas is supplied into the processing container 71 via the gas shower head 86 at a desired flow rate. When the HF gas is supplied into the processing container 71, for example, an Ar gas and an N₂ gas are also supplied into the processing container 71 as a carrier gas.

Furthermore, instead of supplying the HF gas to the wafer W as the roughness reducing gas, an NH₃ gas may be supplied to the wafer W. When the NH₃ gas is supplied in this manner, the NH₃ gas reacts with the fluorine component contained in the AFS layer 31 formed in step T1 to generate a reaction product. It is considered that the reaction product slightly etches the surface layer of the Si film 13 coated on the AFS layer 31, thereby reducing roughness.

When the NH₃ gas is used as the roughness reducing gas, for example, the F₂ gas and the NH₃ gas may be supplied together as the processing gases, and the NH₃ gas may be continued to be supplied to the wafer W even after the supply of the F₂ gas is stopped, thereby omitting the purge with the N₂ gas in step T2. In addition, the supply of each of the above-mentioned roughness reducing gases may be performed in any cycle. For example, the supply of each of the above-mentioned roughness reducing gases may be performed in the last cycle of the cycles in each stage, or may be performed in every cycle.

Although it has been described that the temperature of the wafer W is made higher than the temperature during the processing gas supply process in order to remove the reaction products, the present disclosure is not limited thereto. For example, after the above steps T1 and T2 are performed in the processing module 7, the opening degree of the valve 74 arranged in the exhaust pipe 73 may be increased to reduce the pressure in the processing container 71, thereby lowering the sublimation temperature of the reaction products. Accordingly, the present disclosure is not limited to performing one cycle in different processing containers.

As described above, the timings of the ends of supply and the timings of the starts of supply of the F₂ gas and the NH₃ gas, which are processing gases, may be shifted from each other. In addition, the fluorine-containing gas included in the processing gases is not limited to the F₂ gas, and may be, for example, an IF₇ gas, an IF₅ gas, a ClF₃ gas, or an SF₆ gas. Incidentally, “containing fluorine” does not mean that fluorine is contained as an impurity, but means that fluorine is contained as a constituent. Similarly, “containing Ge”, which will be described later, means that Ge is contained as a constituent, not as an impurity.

Moreover, the recess 16 is not limited to being laid horizontally. The present disclosure may be applied to a case where the recess 16 is open vertically and the Si film forming the side wall of such a recess 16 is etched. In that case, the recess 16 can be etched so as to meet the first and second requirements (requirements regarding the roughness and the rectangular shape) among the first to third requirements described above.

It is considered that even if the side wall 23 of the recess 16 is formed by a Ge film instead of the SiGe film 12, it is possible to produce GeF₄ using a fluorine-containing gas and to etch the inner side of the recess 16. Therefore, the side wall 23 of the recess 16 is not limited to being formed by the SiGe film 12, and may be formed by any film including a Ge film.

The embodiments disclosed herein should be considered to be exemplary and not limitative in all respects. The above-described embodiments may be omitted, substituted, modified, or combined in various forms without departing from the scope and spirit of the appended claims.

### [Evaluation Test]

Evaluation tests 1 to 5 performed on this technique will now be described. In each test, a cycle consisting of a processing gas supply process and a heating process is performed on the substrate having the film structure described in FIG. 1 using the apparatus described in the embodiment, and the dimensions of respective portions are measured from SEM images acquired before and after the processing. In evaluation tests 1 to 4, the processing conditions are not changed between the former and latter stage cycles shown in FIG. 10, and the processing is performed under a single processing condition. In evaluation tests 1 to 5, the period during which an F₂ gas is supplied and the period during which an NH₃ gas is supplied in the processing gas supply process coincide with each other. In other words, the timings at which these gases start to be supplied to the processing container 71 are the same, and the timings at which the supply of these gases to the processing container 71 is stopped are also the same.

The following three kinds of dimensions were measured in each evaluation test. One dimension is the horizontal width of the groove 15. Hereinafter, this horizontal width is referred to as a groove width dimension. Another dimension is the vertical width of the recess 16 at a position spaced by a predetermined small distance from the opening of the recess 16 toward the inner side of the recess 16. Hereinafter, this vertical width is referred to as an opening side dimension. A further dimension is the vertical width of the recess 16 at a position spaced by a predetermined small distance from the side wall 23 of the recess 16 toward the opening of the recess 16. Hereinafter, this vertical width is referred to as an inner side dimension.

Among the recesses 16 formed in multiple stages, a plurality of recesses 16 in predetermined stages are regarded as top recesses 16 in the evaluation tests. For each of the groove width dimension, the opening side dimension, and the inner side dimension of the top recesses 16, (dimension after etching—dimension before etching)/2 is calculated. This calculation is performed for each of the plurality of top recesses 16. Then, for each of the calculated values obtained from the groove width dimension, the calculated values obtained from the opening side dimension, and the calculated values obtained from the inner side dimension, average values among the recesses 16 are calculated, and the obtained average values are regarded as a groove width etching amount, an opening side etching amount, and an inner side etching amount in the top recesses 16. The groove width dimension of each top recess 16 is obtained from between the upper walls 21 of the recesses 16 facing each other in the horizontal direction.

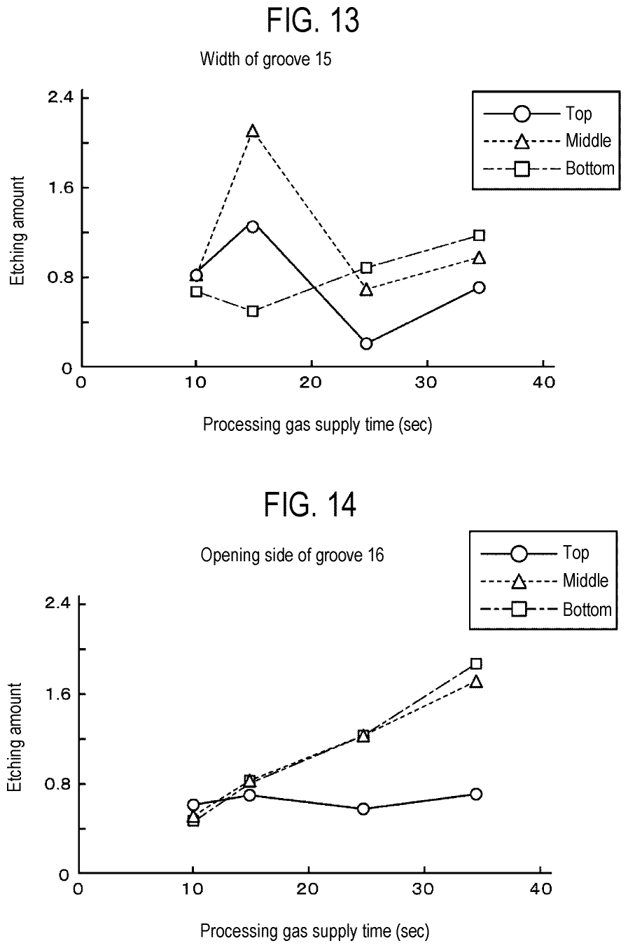

Similarly, a plurality of recesses 16 in predetermined stages are regarded as middle recesses 16 and bottom recesses 16, respectively. A groove width etching amount, an opening side etching amount, and an inner side etching amount are calculated for each of the middle recesses 16 and the bottom recesses 16. The etching amounts calculated in this way are divided by a predetermined reference amount, and standardized values are obtained as shown in FIGS. 13 to 15. The larger the standardized value, the larger the actual etching amount. Each etching amount (i.e., actual measured value) before test standardization obtained in each evaluation test is a value of 20 nm or less. As for evaluation tests 3 to 5, as the test results, there are shown tables that indicate the shape of the recesses 16 and the roughness of the recesses 16 after etching. In each table, the recesses having a clear rectangular shape and the recesses having a clear round shape are indicated as “Rectangle” and “Round”, respectively, and the recesses having other shapes are indicated as “Intermediate”. Therefore, since the recesses which are not clearly rectangular but have a relatively high degree of rectangularity that does not pose a problem in practical use are also indicated as “Intermediate” in the tables, the processing conditions which result in “Rectangle” are not the only processing conditions that can be used in practice. In the tables, the recesses which have neither micro-roughness nor large roughness and are highly smooth are indicated as “Smooth”.

### Evaluation Test 1

In evaluation tests 1-1 to 1-3, substrates were etched by repeating a cycle of a processing gas supply process and a heating process. The combination of the number of cycles and the pressure in the processing container 71 during the processing gas supply process was changed between evaluation tests 1-1 to 1-3. In evaluation test 1-1, the pressure in the processing container 71 was 200 Pa (1.5 Torr), and the number of cycles was 9. In evaluation test 1-2, the pressure in the processing container 71 was 666.6 Pa (5 Torr), and the number of cycles was 9. In evaluation test 1-3, the pressure in the processing container 71 was 666.6 Pa (5 Torr), and the number of cycles was 3. Each processing condition, such as the temperature of the wafer W during the processing gas supply, the supply time of the process gases, or the NH₃ gas flow rate ratio, was set to a value falling within the range described in the embodiment.

The results of evaluation test 1 indicate the average values of the values obtained from the top, middle, and bottom recesses 16. In evaluation test 1-1, the groove width etching amount was 1.26, the opening side etching amount was 1.62, and the inner side etching amount was 1.66. In evaluation test 1-2, the etching progressed significantly, causing the upper wall 21 and the lower wall 22 to disappear, and each etching amount could not be measured. In evaluation test 1-3, the disappearance of the upper wall 21 and the lower wall 22 was prevented, and the groove width etching amount was 1.78, the opening side etching amount was 1.9, and the inner side etching amount was 1.9.

From the above results of evaluation test 1, it is noted that the etching rate can be increased by relatively increasing the pressure in the processing container 71 when the processing gases are supplied, and excessive etching can be prevented by appropriately setting the number of cycles. It is also noted that the pressure in the processing container 71 is preferably greater than 1.5 Torr (200 Pa), and more preferably equal to or greater than 5 Torr (666.6 Pa).

### Evaluation Test 2

In evaluation tests 2-1 to 2-5, each substrate was processed by performing the processing gas supply process and the heating process once, without repeating the cycle of these processes. The processing gas supply time was set to different values between evaluation tests 2-1 to 2-5, and was set to 5 seconds, 10 seconds, 15 seconds, 25 seconds, and 35 seconds in evaluation tests 2-1, 2-2, 2-3, 2-4, and 2-5, respectively. In addition, each processing condition, such as the NH₃ gas flow rate ratio, the temperature of the wafer W during the processing gas supply, or the pressure inside the processing container 71, was set to a value falling within the range described in the embodiment.

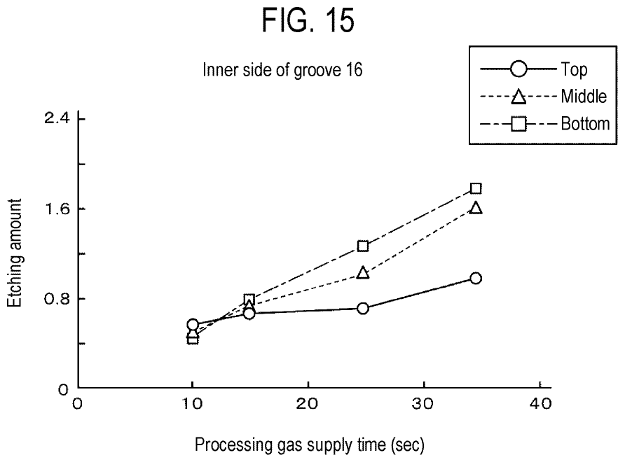

The graphs of FIGS. 13 to 15 described below summarize the etching amounts in evaluation test 2. Each graph shows the relationship between the etching amount and the processing gas supply time, wherein the vertical axis indicates the etching amount and the horizontal axis indicates the supply time. FIG. 13 shows the groove width etching amount, FIG. 14 shows the opening side etching amount, and FIG. 15 shows the inner side etching amount.

As is clear from the graph of FIG. 13, the etching amount in the horizontal direction of the groove 15 is less related to the processing gas supply time for each of the top, middle, and bottom. As is clear from the graphs of FIG. 14 and FIG. 15, the etching amount on the opening side of the recess 16 and the etching amount on the inner side of the recess 16 are relatively small on the top side when the etching time is relatively long. Presumably, this is because a lot of AFS is generated on the top side as described in the embodiment. The graphs of FIG. 14 and FIG. 15 show that when the etching time is short, the etching amount is larger on the top side, and when the etching time is long, the etching amount is larger on the bottom side. From the graphs of FIG. 14 and FIG. 15, it can be noted that when the processing gas supply time is in the range of 10 seconds to 15 seconds for each of the top, middle, and bottom, the slopes of the graphs are approximately the same, and the difference in the etching amount between the top, middle, and bottom is suppressed. Therefore, evaluation test 2 shows that it is preferable to set the processing gas supply time in one cycle to 10 seconds to 15 seconds.

### Evaluation Test 3

In evaluation tests 3-1 to 3-6, substrates were processed by making the combination of the NH₃ gas flow rate ratio and the processing gas supply time different for each substrate. The number of cycles was 3. The processing gas supply time was set to 10 seconds in evaluation tests 3-1 to 3-3, and to 15 seconds in evaluation tests 3-4 to 3-6. The NH₃ gas flow rate ratio was set to 0.01 in evaluation tests 3-1 and 3-4, 0.014 in evaluation tests 3-2 and 3-5, and 0.02 in evaluation tests 3-3 and 3-6. Other processing conditions were the same as those in evaluation test 2. Table 1 below summarizes the results obtained in evaluation Test 3. In evaluation test 3, the etching amount of each portion was obtained in the same way as in evaluation test 2.

TABLE 1

| | Evaluation Test | | | | | |
|---|---|---|---|---|---|---|
| | 3-1 | | 3-2 | | 3-3 | |
| Processing | 10 sec | | 10 sec | | 10 sec | |
| gas supply | | | | | | |
| time | | | | | | |
| NH₃ gas | 0.01 | | 0.014 | | 0.02 | |
| flow rate | | | | | | |
| ratio | | | | | | |
| Number of | 3 | | 3 | | 3 | |
| cycle | | | | | | |
| | Shape | Roughness | Shape | Roughness | Shape | Roughness |
| Top | Rectangle | Smooth | Intermediate | Smooth | Intermediate | Large |
| Middle | Rectangle | Micro | Intermediate | Smooth | Intermediate | Smooth |
| Bottom | Rectangle | Micro | Rectangle | Micro | Intermediate | Smooth |
| | Evaluation Test | | | | | |
| | 3-4 | | 3-5 | | 3-6 | |
| Processing | 15 sec | | 15 sec | | 15 sec | |
| gas supply | | | | | | |
| time | | | | | | |
| NH₃ gas | 0.01 | | 0.014 | | 0.02 | |
| flow rate | | | | | | |
| ratio | | | | | | |
| Number of | 3 | | 3 | | 3 | |
| cycle | | | | | | |
| | Shape | Roughness | Shape | Roughness | Shape | Roughness |
| Top | Rectangle | Smooth | Intermediate | Smooth | Intermediate | Large |
| Middle | Rectangle | Smooth | Intermediate | Smooth | Intermediate | Large |
| Bottom | Rectangle | Smooth | Intermediate | Smooth | Intermediate | Large |

Regarding the roughness of the upper wall 21 and the lower wall 22 of the recess 16 after etching, micro-roughness was confirmed in the middle and bottom recesses 16 of evaluation test 3-1. Furthermore, large roughness was confirmed in the top recess 16 of evaluation test 3-3 and in the top, middle, and bottom recesses 16 of evaluation test 3-6. Regarding the shape of the recess 16 after etching, the top, middle, and bottom recesses 16 of evaluation tests 3-1 and 3-4 and the bottom recess 16 of evaluation test 3-2 were rectangular.

Therefore, it was confirmed from evaluation test 3 that micro-roughness was obtained when the NH₃ gas flow rate ratio is relatively small and the etching time is relatively short. It was also confirmed that large roughness was obtained when the NH₃ gas flow rate ratio is relatively large. As described in the embodiment, it is considered that the roughness states are different due to the difference in the amount of AFS produced. It was also confirmed from evaluation test 3 that there is a tendency for a rectangular shape to be formed when the NH₃ gas flow rate ratio is relatively small. It can be seen that in order to form a rectangular shape, it is preferable to make the flow rate ratio smaller than 0.014, and more preferably 0.01 or less.

However, in evaluation tests 3-1, 3-4, and 3-5 in which the NH₃ gas flow rate ratio is set to 0.01 to obtain the rectangular shape, the variation in the amount of etching between the top and bottom was relatively large. Therefore, the results of evaluation tests 3-1 to 3-6 did not sufficiently meet one or more of the first to third requirements.

### Evaluation Test 4

In evaluation tests 4-1 to 4-5, substrates were processed by making the combination of the NH₃ gas flow rate ratio, the processing gas supply time, and the number of cycles different for each substrate. The processing gas supply time was set to 10 seconds, 15 seconds, 15 seconds, 12.5 seconds, and 10 seconds in evaluation tests 4-1, 4-2, 4-3, 4-4, and 4-5, respectively. The NH₃ gas flow rate ratio in the processing gases was set to 0.01 in evaluation tests 4-1, 4-2, and 4-4, and to 0.014 in evaluation tests 4-3 and 4-5, respectively. The number of cycles was set to 3 in evaluation tests 4-1 to 4-4, and 4 in evaluation test 4-5. Other processing conditions were the same as those in evaluation tests 2 and 3. Table 2 below summarizes the results of evaluation Test 4. In evaluation test 4 and evaluation test 5 described below, the etching amount of each portion was obtained in the same way as in evaluation test 3.

TABLE 2

| | Evaluation Test | | | | | |
|---|---|---|---|---|---|---|
| | 4-1 | | 4-2 | | 4-3 | |
| Processing | 10 sec | | 15 sec | | 15 sec | |
| gas supply | | | | | | |
| time | | | | | | |
| NH₃ gas | 0.01 | | 0.01 | | 0.014 | |
| flow rate | | | | | | |
| ratio | | | | | | |
| Number of | 3 | | 3 | | 3 | |
| cycle | | | | | | |
| | Shape | Roughness | Shape | Roughness | Shape | Roughness |
| Top | Rectangle | Smooth | Rectangle | Smooth | Intermediate | Smooth |
| Middle | Rectangle | Micro | Rectangle | Smooth | Intermediate | Smooth |
| Bottom | Rectangle | Micro | Rectangle | Smooth | Intermediate | Smooth |

| | Evaluation Test | | | |
|---|---|---|---|---|
| | 4-4 | | 4-5 | |
| Processing | 12.5 sec | | 10 sec | |
| gas supply | | | | |
| time | | | | |
| NH₃ gas | 0.01 | | 0.014 | |
| flow rate | | | | |
| ratio | | | | |
| Number | 3 | | 4 | |
| of cycle | | | | |
| | Shape | Roughness | Shape | Roughness |
| Top | Intermediate | Smooth | Intermediate | Smooth |
| Middle | Rectangle | Micro | Rectangle | Smooth |
| Bottom | Rectangle | Micro | Rectangle | Micro |

Regarding the roughness of the upper wall 21 and lower wall 22 of the recess 16 after etching, micro-roughness was confirmed in the middle and bottom recesses 16 of evaluation tests 4-1 and 4-4 and in the bottom recess 16 of evaluation test 4-5. The roughness of other recesses 16 was kept within a desirable range. The comparison among evaluation tests 4-1, 4-2, and 4-4, which have the same number of cycles and the same NH₃ gas flow rate ratio indicates that micro-roughness is more likely to obtain when the processing gas supply time is short as described in the embodiment.

Regarding the shape of the recesses 16 after etching, the top, middle, and bottom recesses 16 in evaluation tests 4-1 and 4-2 and the middle and bottom recesses 16 in evaluation tests 4-4 and 4-5 were rectangular, while other recesses 16 were round. The comparison between evaluation tests 4-1, 4-2, and 4-4 indicates that there is a tendency for the recesses 16 to have a rectangular shape when the processing gas supply time is relatively short as described in the embodiment. In addition, in evaluation tests 4-1, 4-2, and 4-4 in which the NH₃ gas flow rate ratio was set to 0.01, two or three of the top, middle, and bottom recesses are rectangular. Therefore, it is noted that in order to obtain a rectangular shape, it is preferable to set the NH₃ gas flow rate ratio to 0.01 or less.

As for the opening side etching amount and the inner side etching amount, in evaluation tests 4-2, 4-4, and 4-5, the top etching amount was larger than the middle and bottom etching amounts. In other words, there was a relatively large variation in the etching amount between the top, middle, and bottom. Furthermore, in evaluation test 4-3, the top etching amount was smaller than the middle and bottom etching amounts. The above results indicate that the recesses 16 of each substrate in evaluation test 4 did not sufficiently meet one or more of the first to third requirements.

By the way, further verification of the results of evaluation test 4 indicates that when the NH₃ gas flow rate ratio is 0.01, the recess 16 tends to be rectangular and the amount of etching of the top tends to be large. Furthermore, when the NH₃ gas flow rate ratio is 0.014, the recess 16 tends to be round and the tendency for the amount of etching of the top to be large is alleviated compared to when the flow rate ratio is 0.01. Moreover, when the NH₃ gas flow rate ratio is 0.01 and 0.014, there are cases where the roughness is reduced within a desirable range. However, when the NH₃ gas flow rate ratio in the processing gases is 0.01 and 0.014, the desired result was not obtained for the roughness when the processing gas supply time is 10 seconds.

Considering the results of evaluation test 4 and the results of evaluation test 2 in which the processing gas supply time is preferably 10 to 15 seconds, the NH₃ gas flow rate ratio in the processing gases may be set to a range greater than 0.01 and less than 0.014, and the processing gas supply time may be set to a range greater than 10 seconds and less than 15 seconds. In other words, it is considered that an allowable range which is more suitable for the first to third requirements than the processing conditions set in evaluation test 4 is searched from such ranges of respective parameters, and processing is performed using values within the allowable range. However, the allowable range for the NH₃ gas flow rate ratio is an even narrower range in the relatively narrow range of 0.01 to 0.014. Therefore, for example, when the film structure to be etched is changed slightly, it is difficult to deal with the change by changing the flow rate ratio, which may lead to a concern that the practicality is low. Therefore, the multi-stage processing performed by changing the processing conditions described in the embodiment is effective.

### Evaluation Test 5

In evaluation tests 5-1 to 5-5, two-stage processing (former stage cycle and latter stage cycle) was performed by changing the processing conditions as described in the embodiment. The combination of the processing conditions in the former stage cycle and the latter stage cycle was changed for each substrate. The processing conditions other than the NH₃ gas flow rate ratio, the processing gas supply time, and the number of cycles were the same as the processing conditions in evaluation test 4.

The NH₃ gas flow rate ratio and the processing gas supply time in the former stage cycle of evaluation tests 5-1, 5-2, and 5-4 and in the latter stage cycle of evaluation tests 5-3 and 5-5 were set to the same processing conditions as the processing conditions under which the rectangular shape is obtained in evaluation test 4. The NH₃ gas flow rate ratio and the processing gas supply time in the latter stage cycle of evaluation tests 5-1, 5-2, and 5-4 and in the former stage cycle of evaluation tests 5-3 and 5-5 were set to the same processing conditions under which the roughness is reduced to fall within a desirable range in evaluation test 4. Table 3 below summarizes the processing conditions and the results of evaluation test 5.

Considering the difference in the number of cycles in addition to the NH₃ gas flow rate ratio and the processing gas supply time, the tendency to form a rectangular shape is as follows: former stage of evaluation test 5-1>former stage of evaluation test 5-2 and latter stage of evaluation test 5-3>former stage of evaluation test 5-4>latter stage of evaluation test 5-5. The tendency to reduce roughness is as follows: latter stage of evaluation test 5-2, former stage of evaluation test 5-3 and former stage of evaluation test 5-5>latter stage of evaluation test 5-1 and latter stage of evaluation test 5-4.

TABLE 3

| | Evaluation Test | | | | | |
|---|---|---|---|---|---|---|
| | 5-1 | | 5-2 | | 5-3 | |
| | Former | Latter | Former | Latter | Former | Latter |
| | stage | stage | stage | stage | stage | stage |
| Processing | 10 sec | 15 sec | 10 sec | 15 sec | 15 sec | 10 sec |
| gas supply | | | | | | |
| time | | | | | | |
| NH₃ gas | 0.01 | 0.014 | 0.01 | 0.014 | 0.014 | 0.01 |
| flow rate | | | | | | |
| ratio | | | | | | |
| Number | 4 | 1 | 2 | 2 | 2 | 2 |
| of cycle | | | | | | |
| | Shape | Roughness | Shape | Roughness | Shape | Roughness |
| Top | Intermediate | Micro | Intermediate | Smooth | Intermediate | Smooth |
| Middle | Rectangle | Micro | Intermediate | Micro | Intermediate | Smooth |
| Bottom | Rectangle | Micro | Rectangle | Micro | Intermediate | Smooth |

| | Evaluation Test | | | |
|---|---|---|---|---|
| | 5-4 | | 5-5 | |
| | Former | Latter | Former | Latter |
| | stage | stage | stage | stage |
| Processing gas | 15 sec | 15 sec | 15 sec | 15 sec |
| supply time | | | | |
| NH₃ gas flow | 0.01 | 0.014 | 0.014 | 0.01 |
| rate ratio | | | | |
| Number of | 2 | 1 | 2 | 1 |
| cycle | | | | |
| | Shape | Roughness | Shape | Roughness |
| Top | Intermediate | Smooth | Intermediate | Smooth |
| Middle | Intermediate | Smooth | Intermediate | Smooth |
| Bottom | Rectangle | Micro | Intermediate | Smooth |

The results of evaluation tests 5-1 to 5-5 are verified for the difference in the amount of etching between the top and bottom. Stating the outline of this verification, the difference in the amount of etching of the recess 16 between the top and bottom obtained from evaluation test 4 is corrected according to the number of cycles. Thus, the expected difference in the amount of etching between the top and bottom when only the former stage cycle in evaluation test 5 is performed and the expected difference in the amount of etching between the top and bottom when only the latter stage cycle in evaluation test 5 is performed are calculated. The expected differences in the amount of etching between the top and bottom are summed up to obtain an expected difference in the amount of etching. This expected difference in the amount of etching and the expected difference in the amount of etching obtained in the process of obtaining the difference in the expected amount of etching are compared with the actual difference in the amount of etching between the top and bottom obtained from evaluation test 5.

To explain more specifically, in evaluation test 5-1, the amount of etching on the opening side of the top and the amount of etching on the inner side of the top are referred to as A1X1 and A2X2, respectively, and the average value thereof is referred to as A3X3. The amount of etching on the opening side of the bottom and the amount of etching on the inner side of the bottom are referred to as B1Y1 and B2Y2, respectively, and the average value thereof is referred to as B3Y3. The value calculated as A3X3-B3Y3 is referred to as a difference in the amount of etching between the top and bottom in evaluation test 5-1. The difference in the amount of etching between the top and bottom calculated in this way was a positive value. Therefore, in evaluation test 5-1, the amount of etching on the top was greater than that on the bottom.

Evaluation tests 4-1 and 4-3 were conducted under the same conditions as the former and latter stage cycles of evaluation test 5-1 except for the number of cycles. For evaluation test 4-1, (average value of the opening side etching amount of the top and the inner side etching amount of the top)−(average value of the opening side etching amount of the bottom and the inner side etching amount of the bottom)=C1A1 was obtained. The number of cycles in evaluation test 4-1 is 3, but the number of cycles in the former stage of evaluation test 5-1 is 4. Therefore, C1A1 was corrected by multiplying by 4/3, and the obtained value was set as a difference in the expected etching amount C2A2 (=C1A1×4/3). The value of C2A2 was a positive value. In other words, the etching amount of the top is larger than that of the bottom.

Similarly, for evaluation test 4-3, which was performed under the same conditions as the latter stage cycle, the difference in the expected etching amount was calculated. Specifically, for evaluation test 4-3, (average value of the etching amount on the opening side of the top and the etching amount on the inner side of the top)−(average value of the etching amount on the opening side of the bottom and the etching amount on the inner side of the bottom)=C1A′1 was calculated. The number of cycles in evaluation test 4-3 is 3, but the number of latter stage cycles in evaluation test 5-1 is 1. Therefore, C1A′1 was corrected by multiplying by ⅓, and the obtained value was set as a difference in the expected etching amount C2A′2(=C′A′1×⅓). The value of C2A′2 was a negative value. In other words, the etching amount of the bottom is larger than that of the top.

The expected total etching amount C2A2+C2A′2 was compared with A3X3-B3Y3 in evaluation test 5-1, indicating that they are almost the same. Furthermore, C2A2 was larger than A3X3-B3Y3. The above calculation results indicate that, even if a relatively large bias in the etching amount occurs between the top side and the bottom side at the end of the first stage of the two-stage processing described in the embodiment, the bias can be offset by performing the second stage processing in which the etching amount is increased on the opposite side of the top side or bottom side in the first stage processing.

As described above, in evaluation test 4-1, each recess 16 was rectangular, and microroughness was obtained in the middle and bottom recesses 16. In evaluation test 4-3, each recess 16 was intermediate in shape, and the roughness of each recess 16 was within a desirable range. In contrast, the test results in evaluation test 5-1 indicate that the middle and bottom recesses 16 were rectangular, and microroughness was obtained in the top, middle, and bottom recesses 16. Therefore, the shape and roughness of the recesses 16 were relatively significantly affected by the processing conditions of the former stage cycle.

When the above verification using calculation was performed for evaluation tests 5-2 to 5-5 in the same manner as in evaluation test 5-1, it was estimated that the bias in the amount of etching between the top side and the bottom side is offset by the execution of the former stage cycle and the latter stage cycle. In the verification, the processing conditions of evaluation tests 4-1 and 4-3 were used in evaluation tests 5-2 and 5-3 as in evaluation test 5-1, but the processing conditions of evaluation test 4-2 were used in evaluation tests 5-4 and 5-5. Therefore, the verification was performed using the data of evaluation test 4-2. In addition, the processing conditions of the former stage cycle and the latter stage cycle of evaluation test 5-2 were the same as those of evaluation test 5-1, and the same as those of evaluation test 4-1 and 4-3 except for the number of cycles. As shown in Table 3, in evaluation test 5-2, the bottom recess 16 was rectangular, and micro-roughness was obtained in each of the middle and bottom recesses 16. Therefore, in even evaluation test 5-2, as in evaluation test 5-1, the influence of the processing conditions of the former stage cycle on the shape and roughness of the recess 16 is relatively large.

Regarding evaluation test 5-3, the former stage cycle and the latter stage cycle are the same as those of evaluation test 4-3 and evaluation test 4-1, respectively, except for the number of cycles. As shown in Table 3, in evaluation test 5-3, the top, middle, and bottom recesses 16 were intermediate in shape, while the roughness thereof was reduced to fall within an allowable range. In evaluation test 4-3, each recess 16 was intermediate in shape, and the roughness of each recess 16 was within an allowable range, whereas in evaluation test 4-1, each recess 16 was rectangular, and micro-roughness was obtained in the middle and bottom recesses 16. Therefore, in evaluation test 5-3 as well, the influence of the processing conditions of the former stage cycle on the shape and roughness of the recess 16 was relatively large.

Regarding evaluation test 5-4, the former stage cycle and the latter stage cycle are the same as those of evaluation test 4-2 and evaluation test 4-3, respectively, except for the number of cycles. As shown in Table 3, in evaluation test 5-4, the bottom recess 16 was rectangular, and micro-roughness was obtained in the bottom recess 16. On the other hand, in evaluation test 4-2, each recess 16 was rectangular, and micro-roughness was obtained in the bottom recess 16. In evaluation test 4-3, each recess 16 was intermediate in shape, and the roughness of each recess 16 was within a desirable range. Therefore, in evaluation test 5-4 as well, the influence of the processing conditions of the former stage cycle on the shape and roughness of the recess 16 was relatively large.

Regarding evaluation test 5-5, the former stage cycle and the latter stage cycle are the same as those of evaluation test 4-3 and evaluation test 4-2, respectively, except for the number of cycles. Furthermore, as described above, in evaluation test 5-5, the roughness of each of the top, middle, and bottom recesses 16 was reduced to fall within an allowable range, and the shape thereof was intermediate. On the other hand, in evaluation test 4-3, each recess 16 was intermediate in shape, and the roughness of each recess 16 was within a desirable range. In evaluation test 4-2, each recess 16 has a rectangular shape, and the bottom recess 16 has micro-roughness. Therefore, in evaluation test 5-5 as well, the influence of the processing conditions of the former stage cycle on the shape and roughness of the recess 16 was relatively large. Incidentally, in evaluation test 5-5, the roughness of the top, middle, and bottom was reduced, and the difference A3X3-B3Y3 in the etching amount between the top and bottom was the smallest in evaluation test 5. The shape of each recess 16 was slightly rounder than that of the recess 16 in evaluation test 5-1 and more rectangular than that of the recess 16 in evaluation test 4-3, and was therefore practical. Therefore, among evaluation tests 5-1 to 5-5, evaluation test 5-5 has the most favorable results.

As described above, it was confirmed from evaluation test 5 that the bias in the amount of etching between the top side and the bottom side in the former stage cycle and the latter stage cycle is offset, and as a result, the amount of etching from the top side to the bottom side can be made highly uniform. It was also confirmed that the processing conditions used in the former stage cycle have a large influence on the shape and roughness of the recess 16 after etching. As described above, the roughness is reduced at the top, middle, and bottom in evaluation tests 5-3 and 5-5. Therefore, it was noted that in order to reduce the roughness in this way, as described in the embodiment, it is preferable to make the NH₃ gas flow rate ratio smaller in the first processing condition of the former stage cycle than in the second processing condition of the latter stage cycle. When evaluation tests 5-3 and 5-5 are compared, the differences in the amount of etching between the top and bottom are different, and the difference in the amount of etching is smaller in evaluation test 5-5 than in evaluation test 5-3. Since the processing gas supply time under the second processing condition differs between evaluation tests 5-3 and 5-5, it can be seen that by adjusting the processing gas supply time between the first and second processing conditions, it is possible to control the balance of the etching amount between the top, middle, and bottom while reducing the roughness of each recess 16.

Regarding the rectangularity of the recess 16, the results of evaluation tests 5-1, 5-2, and 5-4 indicate that in order to improve the rectangularity, it is preferable to make the NH₃ gas flow rate ratio smaller under the first processing condition than under the second processing condition. Since evaluation test 5-1 has the highest rectangularity, it was confirmed that in order to obtain a higher rectangularity, it is preferable to make the processing gas supply time shorter under the first processing condition than under the second processing condition.

According to the present disclosure, it is possible to reduce the roughness of an etched surface of a silicon film that forms a recess, and to control the shape of the recess.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing method, comprising:
a first step of supplying processing gases including a halogen-containing gas and a basic gas to a substrate having a recess with side walls formed of a silicon film and an inner wall formed of a germanium-containing film to alter a surface of the silicon film and produce a reaction product;
a second step of removing the reaction product to widen a width of the recess;
a step of performing a cycle including the first step and the second step multiple times; and
a step of performing the first step of a former cycle under a first processing condition and performing the first step of a latter cycle under a second processing condition different from the first processing condition.

2. The method of claim 1, wherein the first processing condition and the second processing condition differ in at least one of a ratio of the basic gas to the halogen-containing gas in the processing gases and a supply time of the processing gases.

3. The method of claim 2, wherein the ratio of the basic gas to the halogen-containing gas is smaller under the first processing condition than under the second processing condition, or the supply time of the processing gases is shorter under the first processing condition than under the second processing condition.

4. The method of claim 2, wherein the ratio of the basic gas to the halogen-containing gas is larger under the first processing condition than under the second processing condition, or the supply time of the processing gases is longer under the first processing condition than under the second processing condition.

5. The method of claim 3, wherein the recess includes a plurality of recesses formed in multiple stages in a thickness direction of the substrate, and each of the recesses is opened in a direction intersecting the thickness direction.

6. The method of claim 2, wherein the halogen-containing gas is a first fluorine-containing gas, and the basic gas is an ammonia gas.

7. The method of claim 6, wherein the first fluorine-containing gas is a fluorine gas.

8. The method of claim 1, wherein the germanium-containing film is a silicon germanium film.

9. The method of claim 2, wherein under one of the first processing condition and the second processing condition, the ratio of the basic gas to the halogen-containing gas is less than 0.014.

10. The method of claim 2, wherein under the first processing condition and the second processing condition, the supply time of the processing gases is 10 to 15 seconds.

11. The method of claim 10, wherein the first step includes a step of supplying the processing gases into a processing container storing the substrate in a state in which a pressure inside the processing container is greater than 200 Pa.

12. The method of claim 1, wherein the first step includes a first supply step in which the halogen-containing gas and the basic gas are supplied to the substrate in parallel; and a second supply step in which only one of the halogen-containing gas and the basic gas is supplied to the substrate after the first supply step.

13. The method of claim 12, wherein the halogen-containing gas includes a first fluorine-containing gas supplied to the substrate in the first supply step, and a second fluorine-containing gas supplied to the substrate in the second supply step, and
the first fluorine-containing gas and the second fluorine-containing gas are different from each other.

14. The method of claim 13, wherein the first fluorine-containing gas is a fluorine gas, and the second fluorine-containing gas is a hydrogen fluoride gas.

15. A substrate processing apparatus, comprising:
a first processing part configured to supply processing gases including a halogen-containing gas and a basic gas to a substrate having a recess with side walls formed of a silicon film and an inner wall formed of a germanium-containing film to alter a surface of the silicon film and produce a reaction product;
a second processing part configured to remove the reaction product to widen a width of the recess; and
a controller configured to perform a cycle including a process using the first processing part and a process using the second processing part multiple times, and configured to perform the process using the first processing part of a former cycle under a first processing condition and perform the process using the first processing part of a latter cycle under a second processing condition different from the first processing condition.

16. The method of claim 4, wherein the recess includes a plurality of recesses formed in multiple stages in a thickness direction of the substrate, and each of the recesses is opened in a direction intersecting the thickness direction.
